(19) United States
(12) Patent Application Publication
(10) Pub. No.: US 2022/0154480 A1
(43) Pub. Date: May 19, 2022

(54) INTEGRATED COMPONENT-BASED CONSTRUCTION COMPONENTS AND RELATED METHODS

(71) Applicant: IP FACTORS, LLC, Los Angeles, CA (US)

(72) Inventor: Farhad Vafaee, Los Angeles, CA (US)

(21) Appl. No.: 17/527,680

(22) Filed: Nov. 16, 2021

Related U.S. Application Data
(60) Provisional application No. 63/114,323, filed on Nov. 16, 2020.
(60) Provisional application No. 63/114,341, filed on Nov. 16, 2020.
(60) Provisional application No. 63/114,349, filed on Nov. 16, 2020.
(60) Provisional application No. 63/114,390, filed on Nov. 16, 2020.
(60) Provisional application No. 63/114,401, filed on Nov. 16, 2020.
(60) Provisional application No. 63/114,408, filed on Nov. 16, 2020.
(60) Provisional application No. 63/114,417, filed on Nov. 16, 2020.
(60) Provisional application No. 63/114,426, filed on Nov. 16, 2020.
(60) Provisional application No. 63/114,452, filed on Nov. 16, 2020.
(60) Provisional application No. 63/114,460, filed on Nov. 16, 2020.
(60) Provisional application No. 63/114,468, filed on Nov. 16, 2020.
(60) Provisional application No. 63/114,472, filed on Nov. 16, 2020.
(60) Provisional application No. 63/114,476, filed on Nov. 16, 2020.
(60) Provisional application No. 63/114,485, filed on Nov. 16, 2020.
(60) Provisional application No. 63/114,489, filed on Nov. 16, 2020.
(60) Provisional application No. 63/114,492, filed on Nov. 16, 2020.
(60) Provisional application No. 63/115,497, filed on Nov. 18, 2020.
(60) Provisional application No. 63/114,755, filed on Nov. 17, 2020.

(51) Int. Cl. E04G 21/18

(52) U.S. Cl. CPC E04G 21/1891

(57) ABSTRACT

A construction component for use in integrated component-based construction that includes a base member having a predetermined size and a marking fixed to an exterior surface of the base member. The marking including an identifier and at least one indicator, wherein the identifier identifies the base member's location in a centralized building model and the at least one indicator indicates a location of a second construction component relative to the base member.

### CROSS-REFERENCE TO RELATED APPLICATIONS

This application claims the benefit of U.S. Provisional Application No. 63/114,323, filed on Nov. 16, 2020, U.S. Provisional Application No. 63/114,341, filed on Nov. 16, 2020, U.S. Provisional Application No. 63/114,349, filed on Nov. 16, 2020, U.S. Provisional Application No. 63/114,390, filed on Nov. 16, 2020, U.S. Provisional Application No. 63/114,401, filed on Nov. 16, 2020, U.S. Provisional Application No. 63/114,408, filed on Nov. 16, 2020, U.S. Provisional Application No. 63/114,417, filed on Nov. 16, 2020, U.S. Provisional Application No. 63/114,426, filed on Nov. 16, 2020, U.S. Provisional Application No. 63/114,452, filed on Nov. 16, 2020, U.S. Provisional Application No. 63/114,460, filed on Nov. 16, 2020, U.S. Provisional Application No. 63/114,468, filed on Nov. 16, 2020, U.S. Provisional Application No. 63/114,472, filed on Nov. 16, 2020, U.S. Provisional Application No. 63/114,476, filed on Nov. 16, 2020, U.S. Provisional Application No. 63/114,485, filed on Nov. 16, 2020, U.S. Provisional Application No. 63/114,489, filed on Nov. 16, 2020, U.S. Provisional Application No. 63/114,492, filed on Nov. 16, 2020, U.S. Provisional Application No. 63/115,497, filed on Nov. 18, 2020, and U.S. Provisional Application No. 63/114,755, filed on Nov. 17, 2020. The entire disclosures of each of the above applications are incorporated herein by reference.

### FIELD

The present disclosure relates to integrated component-based construction components and related methods. More particularly, the present disclosure relates to components and related methods that can be used in an integrated construction process.

### BACKGROUND

This section provides background information related to the present disclosure which is not necessarily prior art.

Traditional construction methods and related systems often include the preparation of a design and then the use of general contractors and/or skilled trades people to build the construction project based on the design. The contractors and skilled trades people often possess industry and trade knowledge and skills that enable such individuals to perform the necessary steps to complete the construction project efficiently and adequately to meet various requirements for the project such as price, timing, function, zoning, safety, durability and the like. The building materials used during construction projects using such traditional methods and systems often are sourced from a variety of vendors, suppliers and manufacturers that may have purchasing programs or relationships with the traditional contractors and/or trades people.

These traditional construction methods and systems, however, suffer from problems and drawbacks. For example, such traditional construction methods and systems require the individualized and/or specialized knowledge of the contractors and/or skilled tradespeople. Without such individuals, such as during labor shortages, increases in building demand or in geographic areas without such individuals, construction projects can be difficult to complete. Furthermore, when the availability of individuals with sufficient knowledge and skill is low, the quality, price, durability and safety of construction projects can suffer. Still further, the availability, timing and delivery of construction building materials can be slow, costly and inefficient using traditional supply chains that use traditional building material suppliers, vendors and manufacturers.

In other existing construction methods and systems, pre-fabricated construction projects can allow for all or portions of a construction project to be performed remote from a construction site. Such pre-fabricated construction projects or portions thereof can then be transported from the building location to the construction site. Such pre-fabricated construction methods and systems also suffer from problems and drawbacks. For example, existing pre-fabricated construction methods and systems often allow only for minor variation between construction projects such that the construction projects lack differentiation, personalization and/or the like. Another drawback is that there are limitations on what size, shape, weight and/or configuration can be transported from a building location to a construction site.

Therefore, there exists a need for improved construction methods and components that address the problems and drawbacks of existing processes.

### SUMMARY

This section provides a general summary of the disclosure, and is not a comprehensive disclosure of its full scope or all of its features.

The integrated component-based construction (ICBC) components and methods of the present disclosure include various construction components that may have predefined characteristics and can be selected by a user to build or design construction projects. The ICBC component may include a marking that is fixed to an exterior surface of the component to identify the component and to identify other installation information such as attachment locations of adjacent components, fabrication information to describe modifications to be made to the component and orientation information to describe an orientation of the component in the construction project.

In some embodiments in accordance with the present disclosure, a construction component for use in integrated component-based construction may include a base member having a predetermined size and a marking fixed to an exterior surface of the base member. The marking may include an identifier and at least one indicator, wherein the identifier identifies the base member's location in a centralized building model and the at least one indicator indicates a location of a second construction component relative to the base member.

In one aspect, the marking may be a label that is adhesively connected to the base member.

In another aspect, the marking may be printed onto the base member.

In another aspect, the base member may be a sill plate.

In another aspect, the base member may be a grid template for use to define a building footprint.

In another aspect, the base member may be a beam.

In another aspect, the base member may be a ledger.

In another aspect, the base member may be a joist plate.

In another aspect, the marking may include an orientation indicator that identifies an orientation of the construction component relative to a predetermined location in a building project.

In another aspect, information on the marking may be extracted from the centralized building model.

In some embodiments of the present disclosure, a method of assembling a building project may include determining a building footprint on a building site using one or more grid templates and attaching one or more pre-fabricated sill plates to a foundation. Each sill plate may include a sill marking comprising one or more indicators indicating a location or orientation of one or more complimentary pre-fabricated construction components. The method may also include attaching the one or more complimentary pre-fabricated construction components relative to the one or more pre-fabricated sill plates at a location or in an orientation indicated by the one or more indicators.

In one aspect, the one or more complimentary pre-fabricated construction components may include a wall section.

In another aspect, the wall section may include one or more framing members and a sheathing.

In another aspect, the one or more complimentary pre-fabricated construction components may include an interior sill plate and the interior sill plate defines an interior wall of the building project.

In another aspect, the method may also include removing a portion of the interior sill plate indicated by a cut-on-site indicator on an interior sill marking fixed on an exterior surface of the interior sill plate.

In another aspect, the one or more indicators may include an MEP indicator that indicates a location of a mechanical, electrical or plumbing component.

In another aspect, the one or more indicators may include an attachment indicator that indicates a location of anchor bolt or a hold down.

In another aspect, the one or more grid templates may include a base member and a grid marking fixed to an exterior surface of the base member and the grid marking indicates an orientation of the grid template relative to the building site.

In another aspect, the step of determining the building footprint may include joining the one or more grid templates and positioning the one or more grid templates as indicated by the grid marking.

In another aspect, the step of positioning the one or more grid templates may include aligning the one or more grid templates to at least two set back lines provided by a survey of the building site.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 shows an example environment in which the construction systems and components of the present disclosure can operate and interact.

FIG. 2 shows an example centralized building model in a semi-exploded view.

FIG. 3 shows the centralized building model of FIG. 2 in a further exploded view.

FIG. 4 shows an example building or construction project that can be constructed using the integrated component-based construction components and methods of the present disclosure.

FIG. 5 shows a diagram of an example construction plan that can be determined and used to construction a building project of the present disclosure.

FIG. 6 shows an example grid template component in accordance with the present disclosure.

FIG. 7 shows an example fabrication instruction that can be used to fabricate the grid template component of FIG. 6.

FIG. 8 shows an example face frame component in accordance with the present disclosure.

FIG. 9 shows an example building project that includes multiple ICBC components of the present disclosure.

FIG. 10 shows an example beam component in accordance with the present disclosure.

FIG. 11 shows aspects of an example marking that can be included on the beam component of FIG. 10.

FIG. 12 shows an example identification badge in accordance with the present disclosure.

FIG. 13 shows an example wall section component and its relationship to the centralized construction model in accordance with aspects of the present disclosure.

FIG. 14 shows an example sill component in accordance with the present disclosure.

FIG. 15 shows aspects of an example sill marking that can be fixed to the sill component of FIG. 14.

FIG. 16 shows an example ledger component in accordance with the present disclosure.

FIG. 17 shows aspects of an example ledge marking that can be fixed to the ledger component of FIG. 16.

FIG. 18 shows an example joist plate component in accordance with the present disclosure.

FIG. 19 shows an example building footprint that can be layed out using a grid template of the present disclosure.

FIG. 20 shows an example structure using one or more components of the present disclosure.

FIG. 21 shows an example interior wall layout and example interior sill plate component in accordance with aspects of the present disclosure.

FIG. 22 shows an example exterior wall base assembly in accordance with the present disclosure.

FIG. 23 is a flow chart showing an example method in accordance with aspects of the present disclosure.

Corresponding reference numerals indicate corresponding parts throughout the several views of the drawings.

### DETAILED DESCRIPTION

Example embodiments will now be described more fully with reference to the accompanying drawings. For purposes of the description hereinafter, it is to be understood that the embodiments described below may assume alternative variations and embodiments. It is also to be understood that the specific articles, compositions, and/or processes described herein are exemplary and should not be considered as limiting. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. The terms “couple,” “coupled,” “operatively coupled,” “operatively connected,” and the like should be broadly understood to refer to connecting devices or components together either mechanically, electrically, wired, wirelessly, or otherwise, such that the connection allows the pertinent devices or components to operate (e.g., communicate) with each other as intended by virtue of that relationship.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

In the present disclosure the singular forms “a,” “an,” and “the” include the plural reference, and reference to a particular numerical value includes at least that particular value, unless the context clearly indicates otherwise. When values are expressed as approximations, by use of the antecedent “about,” it will be understood that the particular value forms another embodiment. As used herein, “about X” (where X is a numerical value) preferably refers to ±10% of the recited value, inclusive. For example, the phrase “about 8” preferably refers to a value of 7.2 to 8.8, inclusive. Where present, all ranges are inclusive and combinable. For example, when a range of “1 to 5” is recited, the recited range should be construed as including ranges “1 to 4”, “1 to 3”, “1-2”, “1-2 & 4-5”, “1-3 & 5”, “2-5”, and the like. In addition, when a list of alternatives is positively provided, such listing can be interpreted to mean that any of the alternatives may be excluded, e.g., by a negative limitation in the claims. For example, when a range of “1 to 5” is recited, the recited range may be construed as including situations whereby any of 1, 2, 3, 4, or 5 are negatively excluded; thus, a recitation of “1 to 5 ” may be construed as “1 and 3-5, but not 2”, or simply “wherein 2 is not included.” It is intended that any component, element, attribute, or step that is positively recited herein may be explicitly excluded in the claims, whether such components, elements, attributes, or steps are listed as alternatives or whether they are recited in isolation.

The methods and systems of the present disclosure provide integrated, coordinated processes for the construction of building projects that are more efficient, require less specialized knowledge, and can be completed in less time using less resources than existing methods and systems. The methods and components of the present disclosure may be used in connection with a centralized coordination platform that includes one or more engines that can allow all stakeholders in the value chain to access, design, plan and perform various steps to produce construction projects. One such centralized coordination platform is described in U.S. patent application Ser. No. ______ filed on Nov. 15, 2021, entitled SYSTEMS AND METHODS FOR INTEGRATED COMPONENT-BASED CONSTRUCTION, the entirety of which is incorporated herein by reference. In some examples, the methods and systems of the present disclosure may be used to construct residential building projects. In other examples, the methods and systems of the present disclosure can be used to construction other projects such as commercial or public building projects.

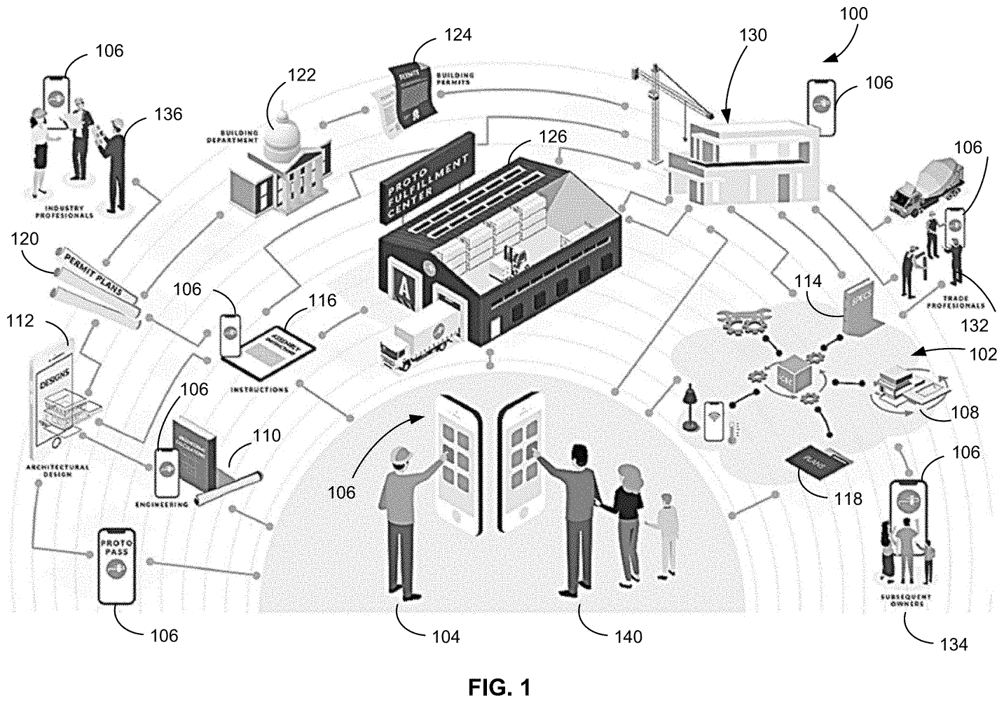

Referring now to FIG. 1, a construction environment 100 is shown. FIG. 1 illustrates an example environment 100 in which the construction systems and the components of the present disclosure may operate in. As shown, a user 140 or builder/contactor 104 can interact with a coordination platform 102 using a construction application 106. As indicated by the mobile phone icon, the various stakeholders in the environment 100 can also interact with the coordination platform 102 either directly or indirectly via a communication network, not shown. The coordination platform 102 can operate to share information and provide access to information during various stages of the construction process.

After a user (e.g., a contractor/builder or customer) engages with the construction system, the entire construction process can be managed and synchronized using the coordination platform 102. During the initial stages, the construction project can be designed and engineered by affiliate service providers 112, 110, respectively. The construction project design can be translated or embodied in a centralized 3D construction model 108 that can be stored in the coordination platform 102. The centralized 3D model 108 can be used to create all documentary information such as design specifications 114, drawings, renderings, etc. This documentation can then be used to create permit plans 120 and shared with other industry professionals 136 and submitted to regulatory authority 122 to obtain the permits 124 required to begin and/or execute the construction project.

The coordination platform 102 can also coordinate and determine a construction plan 118 that can include assembly instructions 116 and can group and allocate the building components and materials into stages, groups or “factors” for the construction of the construction project. As determined by the construction plan 118 and the determined factors, fabrication data, assembly data and/or factor data can be shared with fulfillment center 126 for the manufacturing, fabrication and delivery of the components and materials to the building site 130. Various trade professionals can use the delivered components and materials to complete the factors as scheduled and coordinated by the coordination platform 102. While all these actions are occurring the fulfillment centers 126 and the trade professionals can be interacting with the coordination platform 102 to provide updates on status and progress on completion of tasks. With this information, the coordination platform 102 can share and/or allow access to status information to users such as general contractors 104 and/or customers 140.

Once the construction project is complete, the coordination platform 102 can also serve as an information repository for construction, maintenance and repair information for the subsequent owners 134 of the construction project 130.

As can be seen, the construction systems of the present disclosure and aspects thereof, such as coordination platform 102, provide improvements in efficiency, information sharing, coordination of information and construction tasks over known systems and methods. Furthermore, the construction systems of the present disclosure can provide further added value by serving as information sources regarding the construction, maintenance and repair of construction projects that were built using the construction system(s).

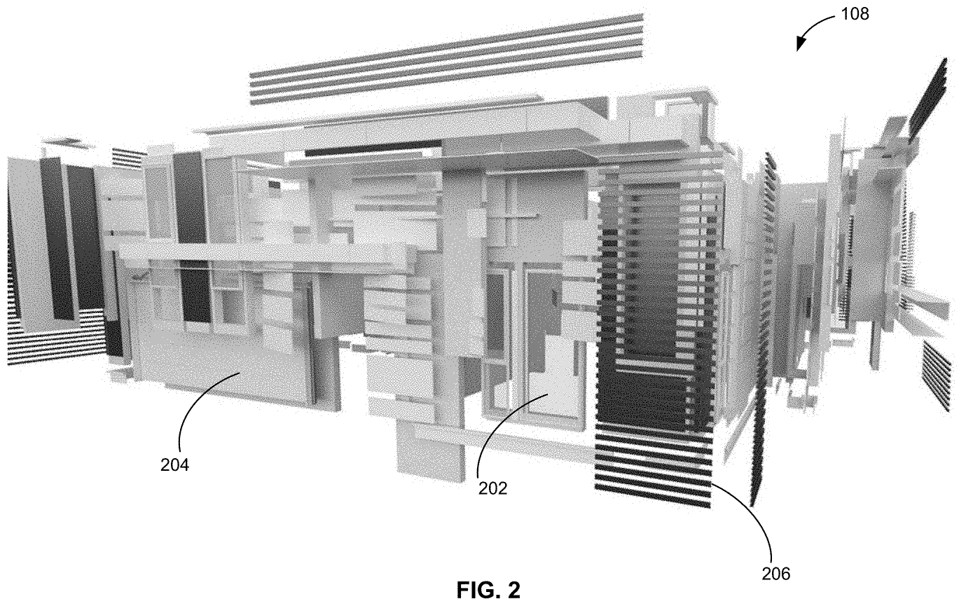

As described above, the coordination platform 102 can store and access information in the form of a centralized 3D construction model 108. The construction model 108 can be can be a 3D parametric model that includes each of the components and/or products that may be used to build the construction project 130. As shown in FIG. 2, the construction model 108 may allow a user to view and/or extract the information regarding the various components that are used to build the construction project. As shown in FIG. 2, the construction model 108 can be viewed in an exploded format that can separate the assembled project into the various components and products. A few examples of the components and products of the construction model 108 are shown in FIG. 2. As shown, the construction model 108 can include information regarding door 202, wall 204, cladding 206 and the like.

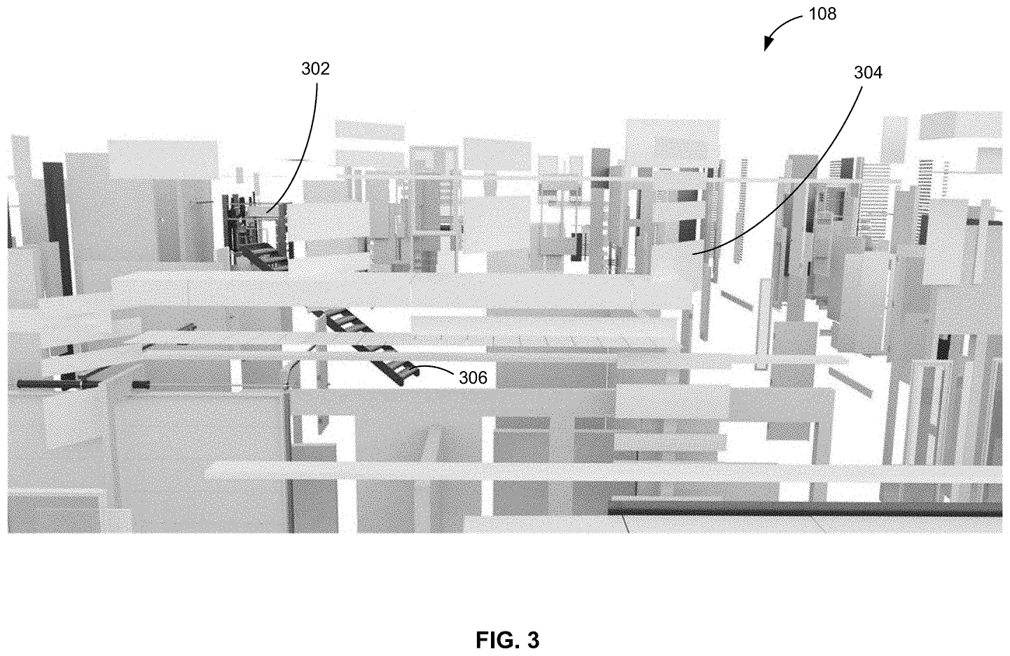

As shown in FIG. 3, the construction model 108 can be further separated and/or viewed in an exploded format to view not only the exterior components and/or products but also the interior components and/or products such as core 302, interior wall 304, staircase 306 and the like. Further details of the core and related aspects are described in U.S. Pat. Appl. No. TBD entitled CENTRALIZED CORE AND NODE SYSTEM FOR CONSTRUCTION PROJECTS filed on Nov. 16, 2021, the contents of which is hereby incorporated by reference in its entirety.

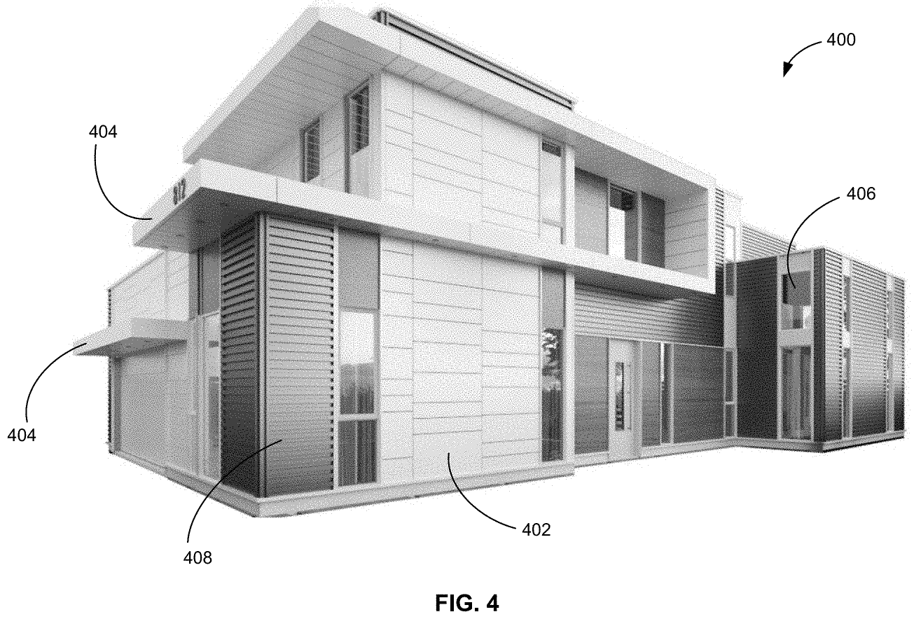

As shown in FIG. 4, an example construction project 400 can be a residential home. The construction project 400 can also be other types of construction projects such as commercial or public buildings or structures. In this example, the construction project 400 can be built using integrated component-based construction (ICBC) technology and components. Integrated component-based construction includes technology, methods and materials that may include a library of components and building processes that standardizes the fabrication and assembly of the construction project 400. Elements of ICBC technology can include standard components, non-standard components and common products.

Standard components can include building components that are proprietary components to the operator of the coordination platform 102. In one example, the standard components can include a library of standard components. The standard components do not change and are typically used in every construction project. There can be more than 100 standard components used on one example of the coordination system 100. Examples of standard components include coping, wall bases, doors, windows, corner trims, rebar matts. Standard components are typically used in the same manner for the same function in various building projects; thus could be inventoried.

Non-standard components are components that are principally the same but may have different design parameters such as different dimensions or different aspects specific to a particular construction project. Non standard components have a unique ID number. The non-standard components may be unique to a specific building project. Because of some of the dimensional characteristics, they often cannot be used in other circumstances. The non-standard components may have to be produced specifically for a building project. However, their family gives them the same consistent characteristics, only with certain dimensional differences. Examples of non-standard components include wall panels, Proto Core, Face Frames, cladding panels, stairs, sill plates, ledger boards, etc.

Common products are products that are commonly used building materials used in many constructions projects. These materials include fasteners, adhesives, sealers, windows and the like that are commonly used in construction projects.

Referring back to FIG. 4, the construction project 400 can include for example a plurality of standard components such as wall panel 402 and siding 408. The construction project 400 may also include non-standard components such as exterior extensions 404. As can be appreciated, the exterior extensions 404 can utilize common elements such as cross-sectional shapes, supports for extending the extensions away from the exterior of the construction project 400 and the like, but may have different lengths (i.e., distances along the exterior of the construction project 400). The construction project 400 can also include common products such as windows 406.

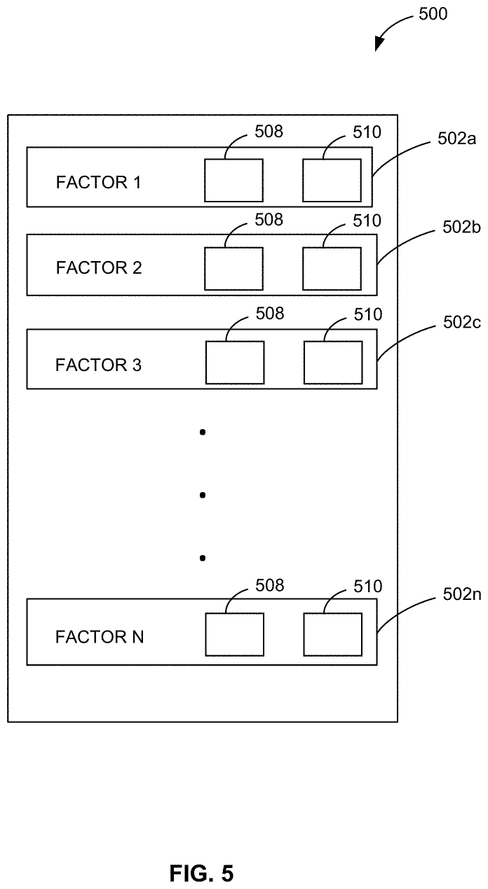

The coordination platform 102 can operate to prepare a construction plan 500. The construction plan 500 can be derived from the construction model 108. Construction plan 500 can include assembly instructions and can be separated into different stages or steps so that each stage of construction. A stage or step of construction can be termed a factor. As shown in FIG. 5, the construction plan 500 can include, in one example, a plurality of factors 502a, 502b, 502c . . . 502n. A factor 502 is a grouping of components, materials and tasks that are performed at a predetermined time during the completion of a construction project. The construction plan 500 can include any number of factors 502 that may be required for completion of a particular construction plan. Factors 502 can be understood to be a particular delineated step of the construction process. Example factors 502 can include for example, Project Kick-off, Footing, Slab, Core, 1st Floor Structure, 2nd Floor Structure, 3rd Floor Structure, Interior Walls and Ceiling, Roofing, Weatherproofing, Interior Doors, Electrical Boxes and Cans, Garage Door, Rough Plumbing, Rough HVAC, Fire Sprinklers, Wiring Electrical, Coping and Wall Base, Arch Projections, Exterior Trim, PVC Cladding, Exterior Painting, Metal Cladding, Accent Cladding, Insulation and Drywall, Tile Work, Interior Painting, Casework and Cabinets, Counter Top, Finish Mechanical, Electrical and Plumbing, Interior Finishes, Appliances, Finish Sprinkler Heads, and Close-out. Further details of electrical systems and components are described in U.S. Pat. Appl. No. TBD entitled INTEGRATED WHOLE HOUSE ELECTRICAL SYSTEMS filed on Nov. 16, 2021, the contents of which is hereby incorporated by reference in its entirety. In other examples, factors 502 can include other steps or stages of construction projects.

Each of the factors 502 above, can include multiple types of information. Each of the factors 502 may include, for example, fabrication information/data 508, and/or assembly information/data 510. The fabrication data 508 can include information that can allow suppliers and/or fulfillment centers to manufacture and/or acquire the materials that are required for a particular factor 502. The fabrication data 508 can include dimensions, materials, quantities, sizes, relationships between components and other information. The fabrication data 508 can also include marking data that indicates to the fulfillment centers and/or suppliers the markings that are to be included on the ICBC components. The assembly data 510 can include information for the construction professionals that describes how the components and products are to be assembled together at the construction site.

Each factor can include its own fabrication data 508 and assembly data 510. In this manner, the components and assembly information can be created and then delivered to the construction site for each factor 502 individually rather than entire loads or amounts of construction materials being shipped and/or delivered to a construction site. This type of step-by-step fabrication, delivery and assembly can simplify the construction process, reduce the likelihood of materials being wasted, stolen or being damaged. Once each factor is completed at the construction site, the next factor 502 can be initiated and then completed. Once all the factors 502 are completed, the construction project is complete.

As discussed above, the coordination platform 102 can determine the construction plan like the construction plan 500 previously described. The coordination platform can use the centralized construction model 108 to determine the various factors 502a to 502n that may be required for a particular construction project. The coordination platform 102 can extract the components for each stage of construction (i.e., each factor 502) and then group the components together for each factor.

The integrated component-based construction (ICBC) components of the present disclosure are improvements over existing components and existing construction methods because the components provide a limited library of components from which a user can design a construction project, such as a residential home. The library of ICBC component allows extensive personalization and flexibility but limits the amount of components from which a builder may access to make the construction process more efficient, faster, less costly and require less resources. Still further, the construction process is different from existing processes because the stakeholders that participate in the construction processes of the present disclosure and that fabricate and/or deliver the ICBC components require less capital because of the limited types of the components that used in the construction projects.

In one example process, the ICBC components of the present disclosure can include standard and non-standard components that are drawn from a library of components. The ICBC components can have information that that is fixed on an exterior surface of the components to provide identification information, assembly information and/or factor information.

As previously described and with reference to FIG. 1, the coordination platform 102 can extract information regarding the components, products and materials that are required to build the construction project 130. The information can be extracted from the centralized construction model 108, for example. This information can then be grouped in the factors (i.e., stages) of assembly. One type of partner in the supply chain that fabricates, sources, bundles and delivers components and materials to the building site 130 is the fulfillment centers 126. The fulfillment centers 126 can be an organization that works as a partner in the construction process but may be independently owned and/or operated separate from the organization that operates the coordination platform 102. In such a manner, the capital required to develop a construction industry in a local geographic region is distributed among multiple parties rather than being concentrated with one entity.

The fulfillment centers 126 can operate multiple pieces of manufacturing and fabrication equipment to prepare and/or manufacture the ICBC components that are used in the construction process. Many different types of ICBC components can be fabricated and/or supplied by the fulfillment centers 126.

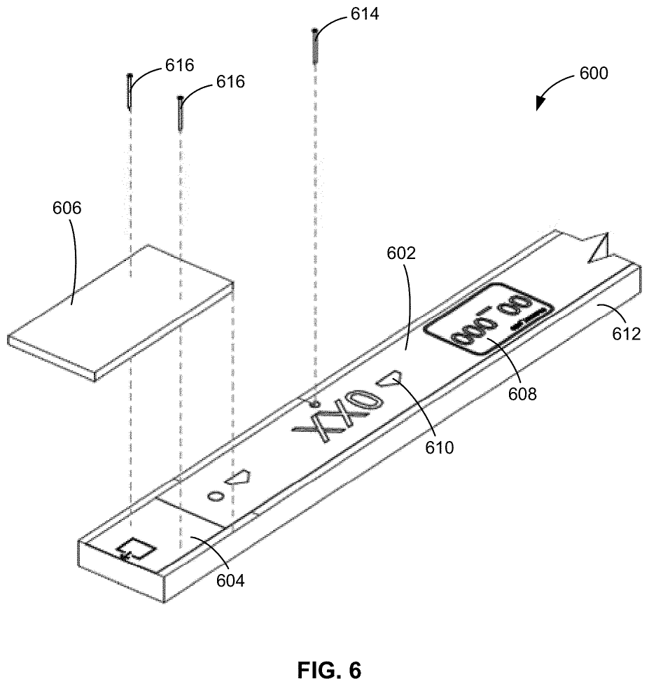

One component that can be fabricated and then delivered by the fulfillment centers is a grid template 600 as shown in FIG. 6. The grid template 600 can be used, for example, to layout the footprint of the construction project at the building site. The grid template 600 can be cut to a predetermined length as determined by the centralized construction model. A marking 602 can be fixed to an external surface of the grid template so the information on the marking 602 can be easily viewed by the builders that will be assembling the building footprint. The marking 602 can include multiple pieces of information such as component identification 608, a joint indicator 604, orientation indicators 610 and the like. The marking 602 can be fixed to the base member 612 of the grid template using any suitable attachment. For example, the base member 612 can be a piece of lumber such as a two by six. The marking 602 can be label that is printed and then fixed to the base member 612 using an adhesive. In other examples, the marking 602 can be printed directly on the base member 612 or may be transferred to the base member using a transfer sticker or the like. Still other examples can include a base member 612 in which the marking 602 can be etched, burned, engraved or otherwise permanently fixed.

The fulfillment center 126 can produce the grid templates 600 as determined by the centralized construction model and cut them to length and secure the joint member 606 at a desired location (as indicated by the joint indicator 604). The multiple grid templates 600 that make up the entire building footprint can then be bundled together and delivered to the building site as part of the grid layout factor. In this example, the joint member 606 may be a piece of plywood or other material that is overlapped at an end of the grid template and secured in position using one or more fasteners 616. Other fasteners 614 may also be installed at the fulfillment center for ease of assembly at the building site.

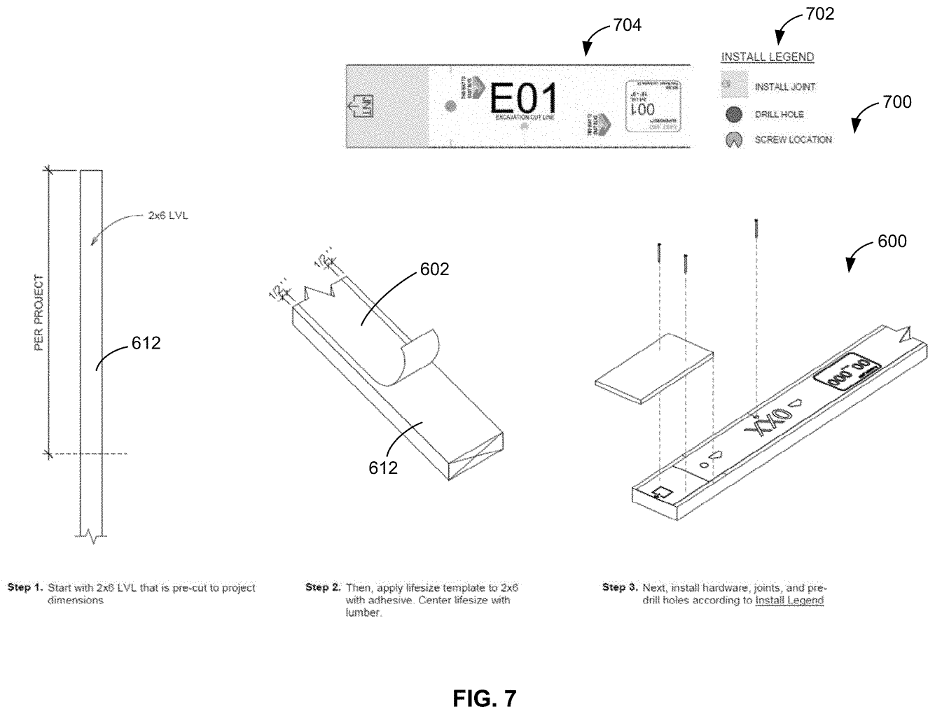

Referring now to FIG. 7, an example fabrication data sheet 700 is shown. The information contained in the fabrication data sheet can be extracted from the centralized construction model and then sent to the fulfillment center 126. The fabrication data sheet can include the steps, dimensions and other information that can be used by the fulfillment center 126 to fabricate the grid template 600. The fabrication data sheet 700 can include multiple steps as shown. In this example, the fabrication data sheet 700 describes a fabrication process of cutting the base member 612 to a predetermined length (step 1), fixing the marking 602 to the base member 612 (step 2) and then installing hardware joints and predrilled holes according to the install legend 702. As can be seen, the install legend 702 can include multiple different indicators that can indicate different operations to be performed on the grid template 600. The indicators, in this example, include a joint indicator, a drill hole indicator and a screw location indicator. The fabrication data sheet 700 can also include a component identifier 704 that identifies the particular grid template 600 that is to be fabricated. A different fabrication data sheet 700 can be provided for each different grid template.

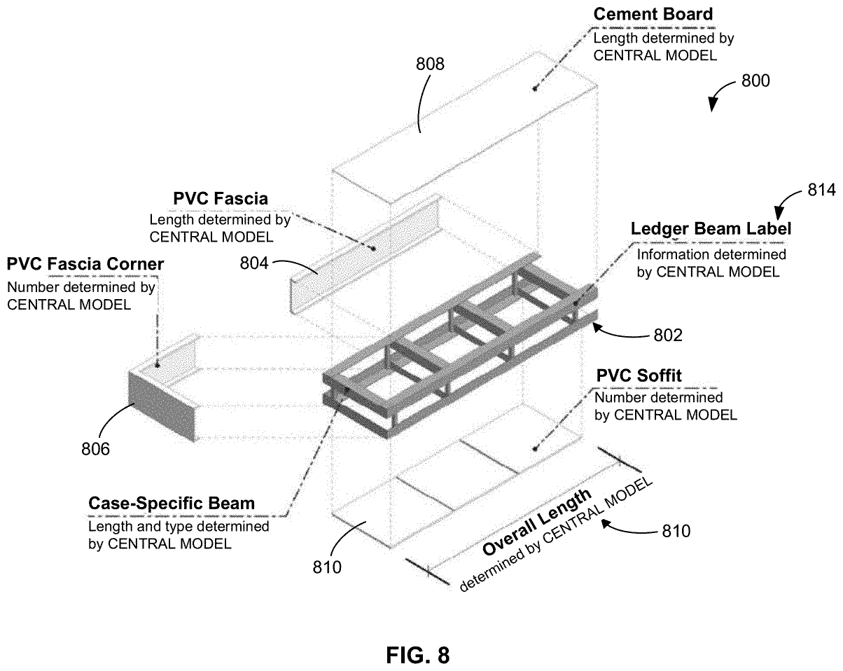

Another example ICBC component is shown in FIG. 8. This example shows a face frame 800. The face frame 800 can be used to an architectural extension (e.g. exterior extension 404, FIG. 4) on the construction project. The face frame 800 can be built using an internal frame 802 of linear members that are coupled together to define a structure having a predetermined shape as defined by the centralized construction model. The frame 802 can then be clad with multiple side claddings 804, 806 and surface claddings 808, 810. In the example shown, the frame 802 is assembled from aluminum members and the claddings are made from poly vinyl chloride (PVC) material. In other examples, other materials can be used. The overall dimensions 810 of the face frame 800 can be determined by the centralized construction model.

Multiple elements of the face frame 800 can be other components that make up the library of components available to build the construction project. The side cladding 804 and the corner fascia 806 can, for example, be stocked in inventor by the fulfillment centers 126. The fulfillment centers 126 need only cut such side cladding 804 to length, if necessary, and then attach the corner fascias 806. In some examples, the side cladding 804 can be stocked in predetermined lengths so that the face frame 800 can only be made to predetermined lengths using multiple of stocked lengths of cladding. Similarly, the aluminum lengths that make up the frame 802 can also be stocked in predetermined lengths. In this manner, the fabrication is relatively easy since little individual cutting and fabrication is needed.

The face frame 800 can also include one or more markings 814. The markings 814 can be fixed to the face frame 800 using the methods previously described. In this example, the marking 814 includes an indicator of the ledge beam to which the face frame 800 should be attached. In this manner, the construction project can be assembled at the building site without the need to consult detailed drawings or architectural renderings.

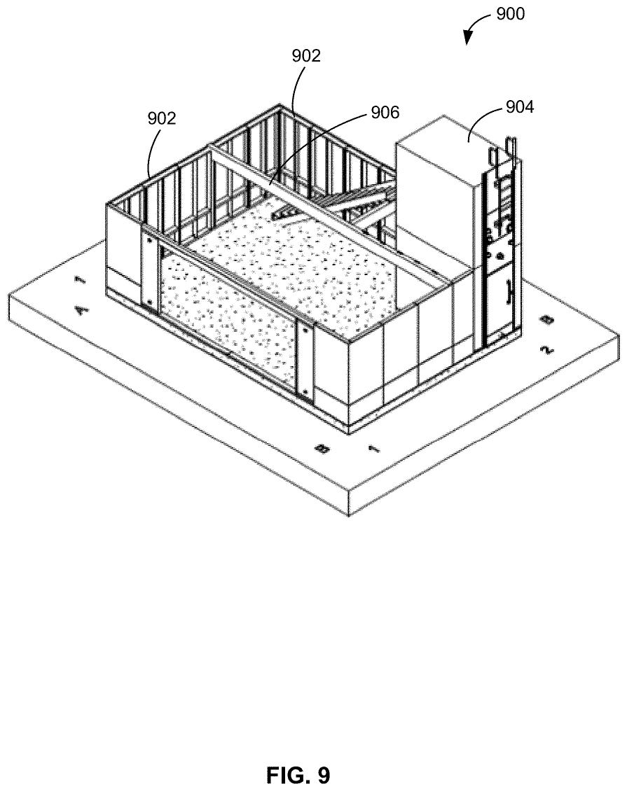

Referring now to FIG. 9, a construction project 900 is shown at an intermediate stage of construction. In this example, the construction project includes exterior walls 902, a proto core 904 and an interior beam 906. The beam 906 can be used, for example, to span a length of the construction project 900 and to support various other elements.

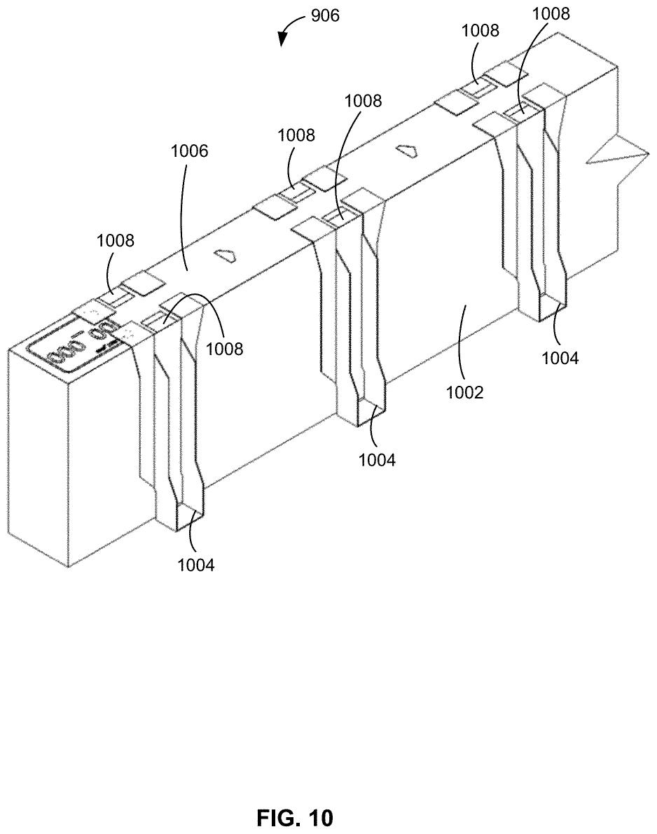

FIG. 10 illustrates an example beam 906. Only a portion of the beam 906 is shown in FIG. 10 for illustration purposes only. As can be appreciated, the beam 906 is longer than that shown and items contained herein may not be shown to scale. The beam 906, in this example, may include a beam base 1002, one or more joist hangers 1004 and a beam marking 1006. The beam base 1002 is the central structural member of the beam 906 and can be made of a suitable piece of lumber, composite or other structural material. The beam marking 1006 is similar to the markings previously described and is fixed to an exterior surface of the beam base 1002. In this example, the beam marking can be a printed label that is fixed to the beam base 1002. In other examples, the marking can be produced using the methods previously described. The beam marking 1006 can include hanger indicators 1008 that identify a location for each of the joist hangers 1004. The fulfillment center 126 can attach the marking to the beam base 1002 and then connect the various hangars to the beam 906.

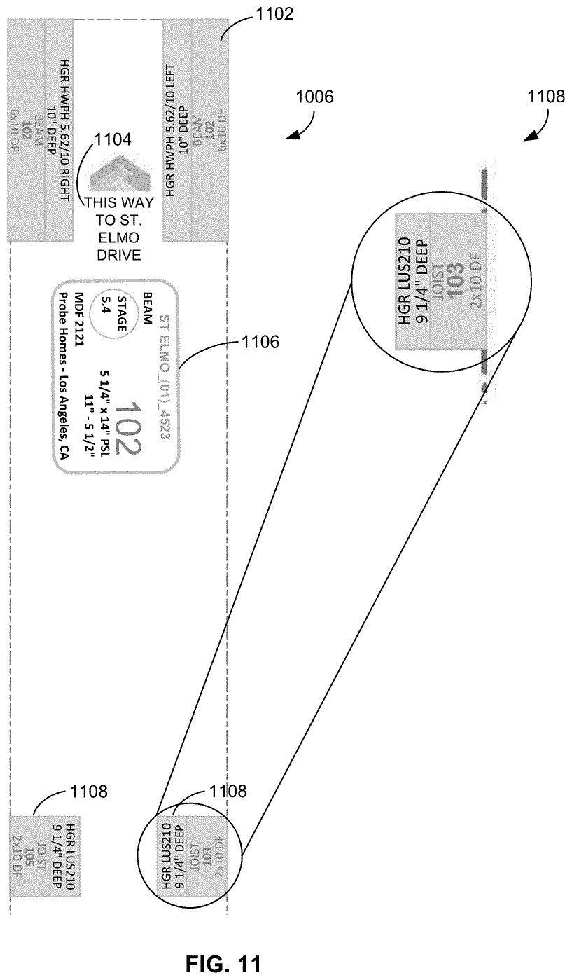

An example beam marking 1006 is shown in FIG. 11. Only a portion of the beam marking 1006 is shown for illustration purposes only. The beam marking 1006 can be a continuous label that extends along the entire length of beam base 1002. In other examples, the markings can be fixed using a printer, etching process, engraving process, or other process, including those previously described. As shown, the beam marking 1006 can, like other markings on other components, include various pieces of information that allow the builder to assemble the components without the need or with little consultation to detailed drawings and architectural plans. The beam marking 1006, in the example, include an end hanger indicator 1102, an orientation indicator 1104, an identification badge 1106 and hanger indicators 1108. The end hanger indicator 1102 can provide information about a hanger that should be attached to the beam 906. The end hanger 1102 may also indicate how the beam 906 is to be attached in the construction projection.

The beam marking 1006 may also include the orientation indicator 1104. This is example, the orientation indicator 1104 includes an arrow and text that identifies the direction that the beam 906 is to be oriented when it is installed in the construction site. As can be appreciated, since this example identifies that the end of the beam 906 should be pointing toward St. Elmo Drive, the builder need not consult detailed assembly drawings and need only orient the beam 906 in the direction indicated. This reduces the likelihood of error and can improve efficiency during the building process.

The beam marking 1006 may also include one or more hanger indicators 1108. FIG. 11 also includes a magnified view of one of the hanger indicators 1108. As can be seen, the hanger indicators 1108 can indicate where hangers (e.g., joist hangers) should be attached to the beam 906 during fabrication at the fulfillment center. Once again, the beam markings 1006 can improve efficiencies and reduce the likelihood of errors during fabrication and/or assembly.

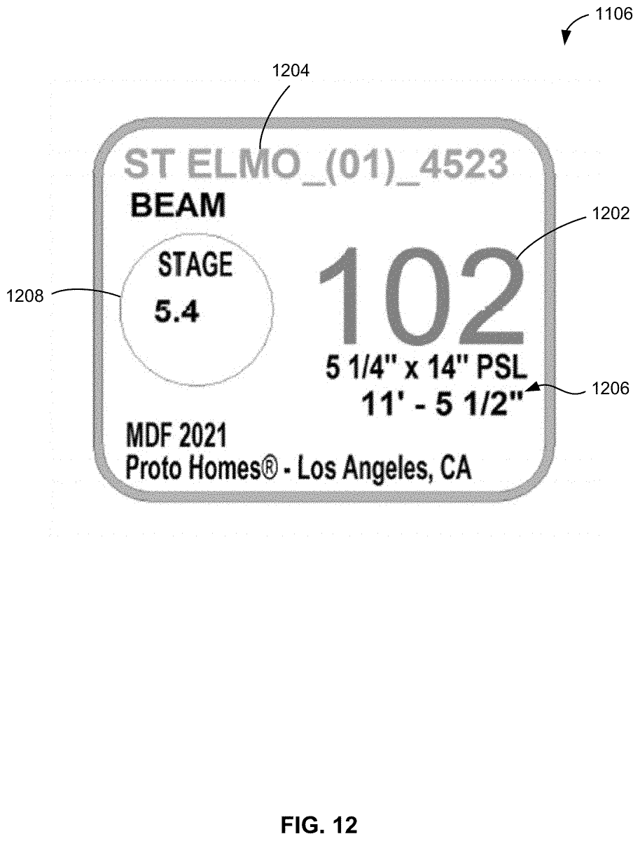

The beam marking 1006 may also include the identification badge 1106. The identification badge 1106 can include information that identifies a unique identification number for the component. In this example, the beam marking 1006 identifies this particular beam 906 as beam number 102. The identification badge 1106 is further shown in FIG. 12. As shown, the identification badge 1106 may include the identification number 1202, a project identifier 1204, dimensional information 1206, and factor identifier 1208. The project identifier 1204 can identify the construction project that the component belongs to. The dimensional information can include information that describes dimensional characteristics of the component. The factor identifier 1208 can identify the factor (e.g., stage) of assembly to which the component belongs. In this example, the beam belongs to factor 5.4. During assembly, the builder can easily identify the stage or assembly to which the component, here a beam, belongs.

Another example ICBC component is shown in FIG. 4. The wall section 1300 can be fabricated at the fulfillment center in accordance with details and information from the centralized construction model 108. The coordination platform 102 can extract such information and provide the fabrication instructions to the fulfillment center 126. In the example shown, the fulfillment center can obtain the fabrication instructions from a construction app on a mobile phone 1302. In other examples, the information can be obtained using a workstation, laptop, or other computing device. As further shown, the centralized construction model 108 can also show and/or provide information where the wall section 1300 will be positioned in the construction project.

The wall section 1300 can be made from pre-framed lumber 1304. In other examples, metal studs or other building materials can be used. The wall section 1300 can also include sheathing 1306 that is pre-installed on the pre-framed portion 1304. The sheating can be any suitable wall board such as plywood, drywall, gypsum, paneling or the like. The wall section 1300 may also include a pre-installed column 1306. The column 1306 can provide structural support to the construction project as may be necessary for door openings, window openings or the like. The wall section 1300 may also include a marking 1310. In the example shown, the marking 1310 is a panel label that is fixed to the wall section 1300. The marking 1310 can include information similar to the previously described such as an identification number and indicator that indicate orientation connection points, and the like.

The wall section 1300 can have a predetermined size to allow for easy installation. For example, the wall section 1300 can be fabricated in four foot or two foot wide wall sections. This allows builders to easily install the section at the building site. The wall section 1300 can be fabricated without a sill plate. The wall section 1300 can be installed on top of the sill plate. The sill plate can include an indication (on the marking) that indicates a location for attachment of the wall section 1300. The wall section 1300 can have fasteners pre-installed in the wall section 1300 to allow the builder to attach the wall section 1300 at the location indicated by the marking on the sill plate.

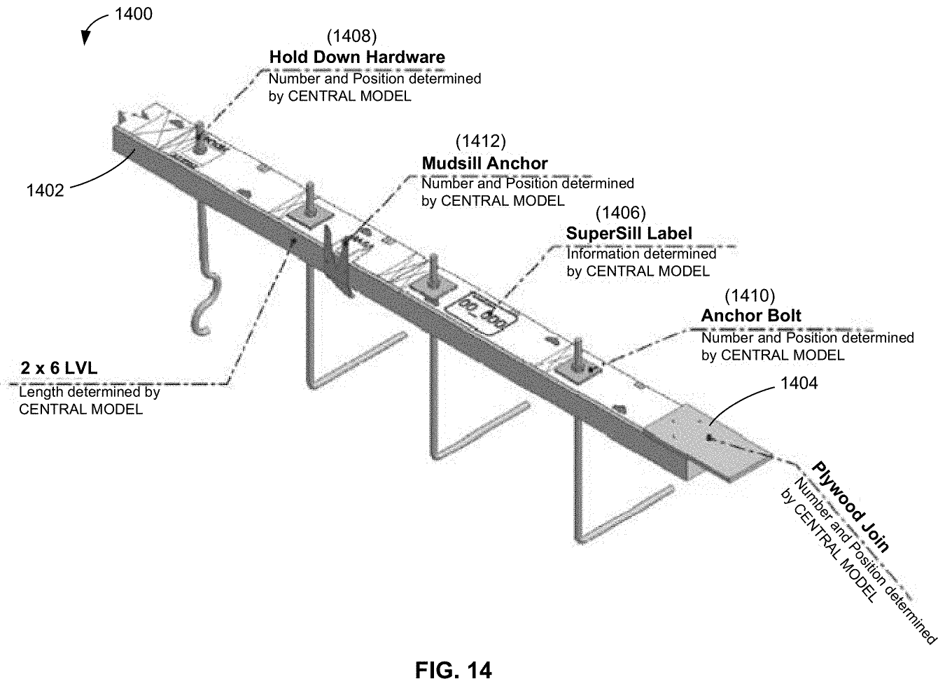

Referring now to FIG. 14, a sill plate 1400 is shown. The sill plate 1400 is another example ICBC component that can be fabricated at a fulfillment center 126 and then delivered to the building site. The sill plate 1400 can include a base member 1402 that can be made of a suitable material such as piece of lumber like a two by six. In other examples, other materials or other sizes can be used. The sill plate 1400 may also include a sill marking 1406. In this example, the sill marking 1406 is a label that is fixed to an exterior surface of the base member 1402. The sill marking 1406 can be fixed to the base member 1402 using other processes as previously described with respect to the other ICBC components. The sill marking 1406 can include various pieces of information to allow the fulfillment center 126 to fabricate the sill plate 1400 before the sill plate 1400 is delivered to the building site. Once at the building site, the marking 1406 can provide further information to the builder to allow the builder to easily, efficiently and accurately assemble the sill plate 1400 in a desired location and in a desired orientation.

As further shown in FIG. 14, the sill plate 1400 can be fixed to a foundation of a building and then wall sections 1300 (or other ICBC components) can be fixed to the sill plate 1400 to build the construction project in a desired manner. In the example shown, the sill plate 1400 can be fixed to a foundation using hold down hardware 1408 and/or an anchor bolt 1410. The sill plate 1400 may also include a mudsill anchor 1412. The sill marking 1406 can include indicators that indicate a location for the hold down hardware 1408, the anchor bolt 1410 and/or the mudsill anchor 1412. The fulfillment center 126 can drill a hole in a predetermined location to allow the sill plate 1400 to be installed over the anchor bolts (or other hardware) when the sill plate plate 1400 is assembled to a foundation of the construction project.

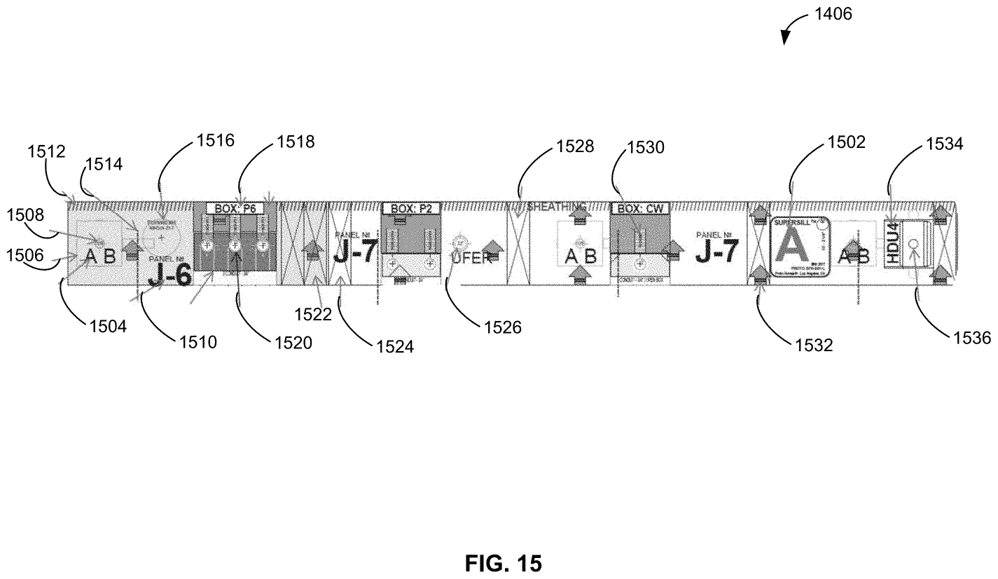

An example sill marking 1406 is shown in FIG. 15. As can be seen, the sill marking 1406 can include many different indicators and information that is then fixed to the base member 1402. Since the sill plate 1400 is positioned at a bottom of each wall section when the construction project is being assembled, the sill plate marking 1406 includes many indicators for the attachment of the wall section and for the position of mechanical, electrical and plumbing (MEP) lines that may extend through the sill plate 1400 and through the wall sections.

The sill marking 1406 can include a sill identification badge 1502. The sill identification badge 1502 can include a name of the construction project, dimensional information and a sill identification number or letter. The sill identification is a unique indicator that identifies the particular sill plate. The sill marking 1406 can also include an anchor bolt indicator 1504. The anchor bolt indicator 1504 can include a washer indicator 1506 that indicates a size and position for a friction anchor bolt washer. The anchor bolt indicator 1504 can also include a hole indicator 1508 that indicates a size and position for the hole that is to be drilled in the sill plate for the anchor bolt.

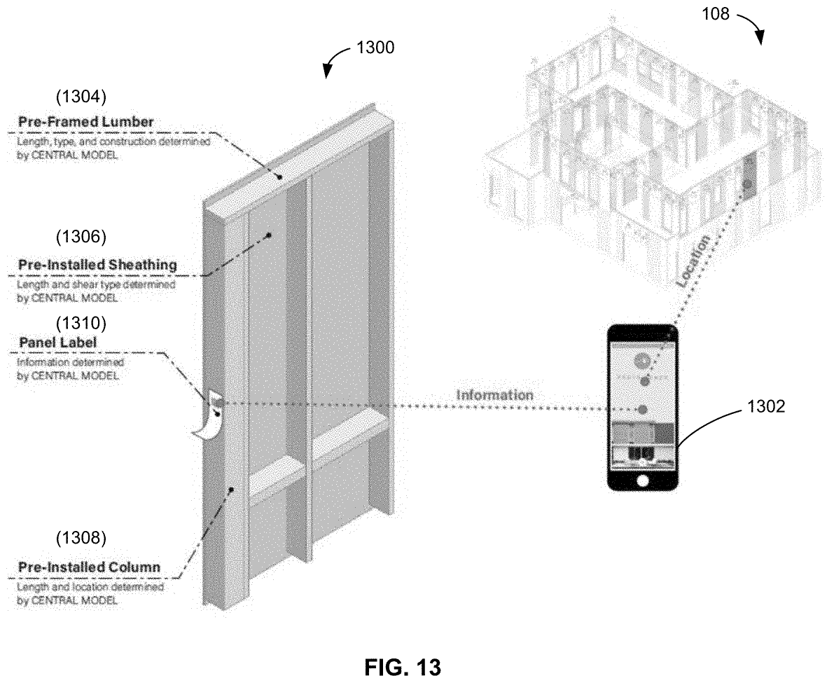

The sill marking 1406 can also include a wall section indicator 1510. The wall section indicator 1510 indicates which wall section (such wall section 1300) is to installed on the sill plate and the position for such installation. In the example shown, the wall section indicator 1510 indicates that wall section J-6 should be installed on the sill plate. The sill marking 1406 can also include a sheathing indicator 1512. The sheathing indicator 1512 indicates the side of the sill plate on which the sheathing 1306 of the wall section 1300 (FIG. 13) should be placed. The sill marking can also include a rebar indicator 1514. The rebar indicator 1514 can indicate a position of the slab rebar layout. An electrical box indicator 1518 can also be included. The electrical box indicator 1518 can indicate a function of the electrical box and can include an electrical box identification. The electrical box indicator 1518 can also include a conduit indicator 1520 that can indicate a size and location of a hole through which the conduit would be placed.

As further shown, the sill marking 1406 indicates an end of a wall panel in a different color than a beginning of an adjacent wall section. As shown, indicator 1522 indicates an end of wall section J-6 and indicator 1524 indicates the start of adjacent wall section J-7. The indicators can also include an indicator of the framing portions of the wall sections. As shown, indicator 1528 indicates a framing member of the wall section J-7. The sill marking 1406 can also include a ufer indicator 1526. The ufer indicator 1526 indicates the location and size of the hole in the sill plate for the ufer ground. A second electrical box indicator 1530 is also shown. The electrical box indicator 1530 can include identifying information that shows location of conduit and other information. As further shown, the sill marking 1406 can also include an orientation indicator 1532. The orientation indicator 1532 can indicate a direction that the sill plate should be installed in the construction project. In one example, the orientation indicator 1532 is marked and should be installed so that all the arrows point toward the same predetermined feature of the construction project. In one example, the predetermined feature is the door of the core. In other examples, other predetermined features can be used. The sill marking 1406 can also include a hold down indicator 1534. The hold down indicator 1534 can identify a location and type of the hold down. The hold down indicator 1534 can also include a hold down hole indicator 1536 that identifies a location and size of hole in the sill plate.

As can be seen, the sill marking 1406 includes detailed and multiple types of information so that it can be easily and accurately installed in the construction project. The sill marking 1406 also includes assembly information that indicates how other components (e.g., wall sections, electrical boxes, MEP components) should be attached and assembled.

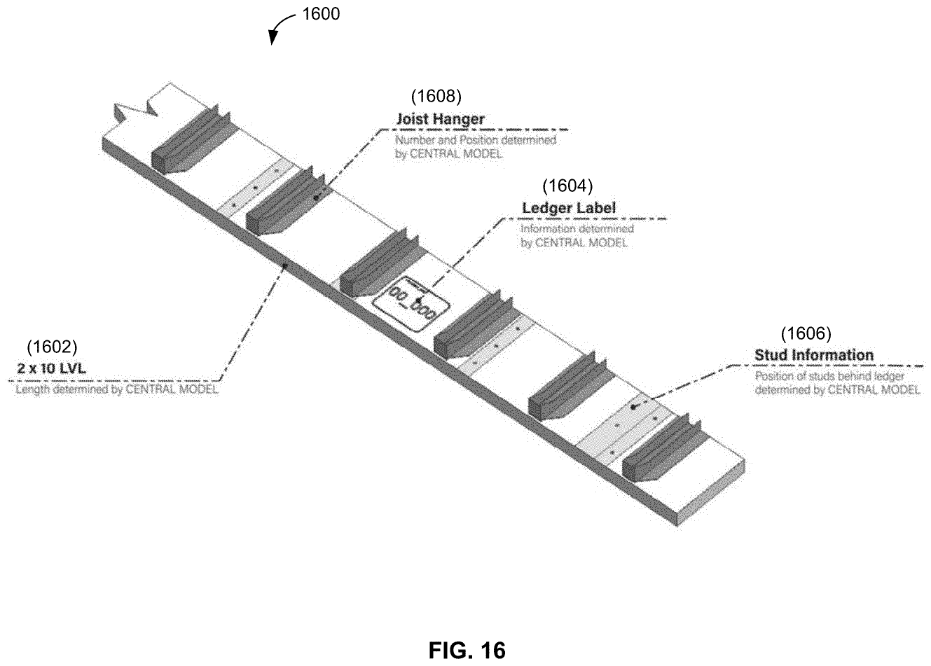

Tuning now to FIG. 16, a ledger 1600 is shown. The ledger 1600 is another example ICBC component. The ledger 1600 can include a ledger base 1602 and a ledger marking 1604. The ledger base 1602 can be length of lumber, such as a two by ten inch piece of lumber, that is cut to predetermined length as indicated by the central construction model and that is included with the fabrication data that is sent to or obtained by a fulfillment center 126. In other examples, the ledger base 1602 can be formed of other materials such as plywood composites or other materials. The ledger marking 1604 can be a label that is fixed to an exterior surface of the ledger base 1602. In other examples, the ledger marking 1604 can be printed, etched or otherwise fixed on the ledger base. Any of the previously described examples for other markings of other ICBC components can be used to fix the ledger marking 1604 to the ledger base 1602. The ledger marking 1604 can include stud indicators 1606 that can indicate a location of studs or other framing members that may be positioned adjacent the ledger 1600 when it is installed. The ledger 1600 may also include one or more joist hangers 1608. The joist hangers 1608 can be installed at locations indicated by the ledger marking 1604 by the fulfillment center 126 prior to the ledger 1600 being delivered to the building site.

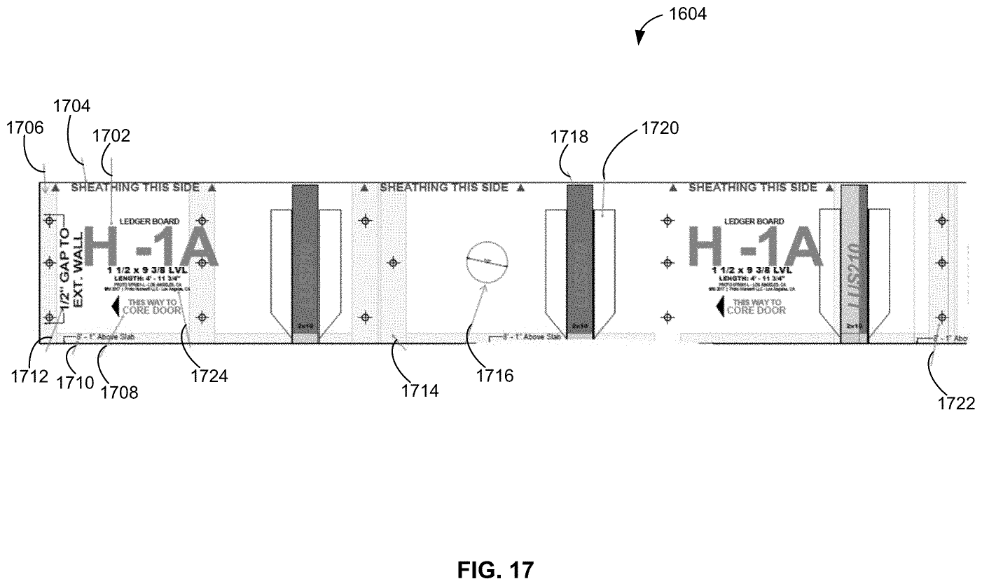

Another example ledger marking 1604 is shown in FIG. 17. Various indicators and markings can be included on the ledger marking 1604 such as MEP penetrations, joist/joist hanger positions, wall framing locations, attachment (e.g., nailing) requirements, position and orientation, and an installation location or height. The example ledger marking 1604 shown in FIG. 17 includes a ledger identification badge 1702. The identification badge 1702 can include a unique identification number or sequence that identifies the specific ledger. The identification badge 1702 can also include an orientation indicator 1708 and a dimensional indicator 1724. The orientation indicator 1708 can identify an orientation of the ledger relative to predetermined location in the construction project. In this example, the orientation indicator 1708 indicates a position of the ledger relative to the core door. In other examples, other predetermined locations can be used.

The ledger marking 1604 can also include a sheathing indicator 1704, an attachment indicator 1706 and position indicators 1710, 1712. The sheathing indicator 1704 can indicate a position of the ledger relative to the sheathing of wall sections. The attachment indicator 1706 can indicate a location of the ledger relative to a stud or other framing member to which the ledger will be attached. The attachment indicator 1706 can include the position of nails, screws or other fasteners that can be pre-attached to the ledger and then used to attach the ledger to the wall sections. The position indicators 1710, 1712 can indicate an installation position of the ledger in the construction project. In this example, the position indicator 1712 indicates that the ledger should be installed with a one-half inch gap to the exterior wall and the position indicator 1710 indicates that the ledger should be installed at a height of eight feet and one inch above the foundation slab. These indicators allow the builder to install the ledger in the proper position without the need for consulting architectural or other detailed drawings.

The ledger marking 1604 can also include other attachment indicators 1714,1722, MEP indicators 1716, and joist indicators 1718, 1720. The attachment indicators 1714, 1722 can be similar to the attachment indicator 1706 previously described and can indicate studs or other framing member to which the ledger is to be attached. The MEP indicator 1716 can indicate mechanical, electrical or plumbing lines that will be positioned through the ledger. In the example shown, the MEP indicator 1716 indicates a hole that should be drilled through the ledger for the positioning of a plumbing line. The hole can be drilled at the fulfillment center 126 prior to delivery to the building site.

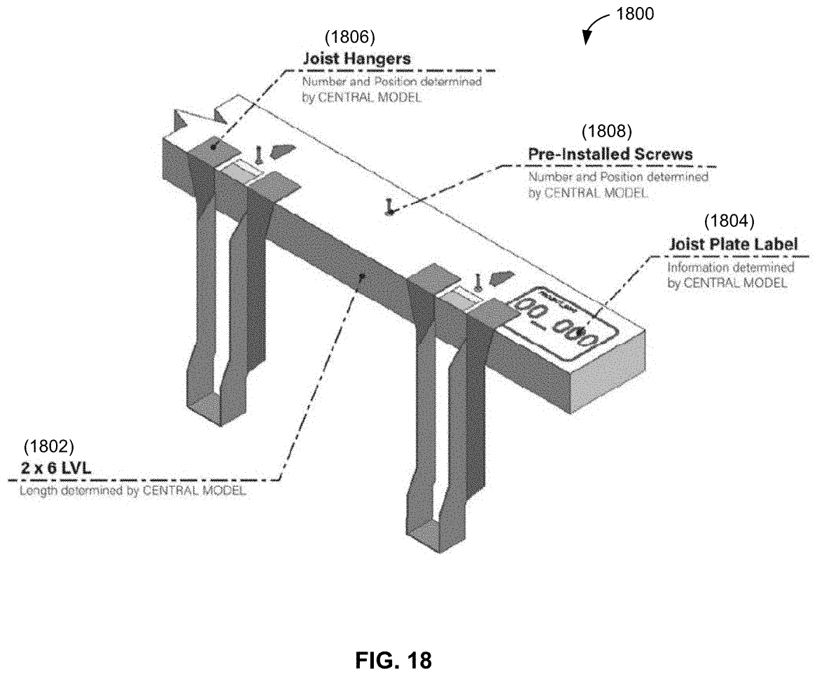

FIG. 18 shows yet another ICBC component. The component shown is a joist plate 1800. The joist plate 1800 can be aligned with and connect the tops of wall sections. The joist plate 1800 can include joist hangers to which joists can be connected. The joist plate 1800 can include joist plate base 1802, joist plate marking 1804, one or more joist hangers 1806 and one or more fasteners 1808. The joist plate 1800 can arrive at the building site with the joist hangers 1806 and the fasteners 1808 pre-installed. The joist plate marking 1804 is similar to the marking previously described and can be fixed to the joist plate base 1802. The joist plate base 1802 can be piece of lumber (e.g., a two by six) or other building material. The joist plate marking 1804 can be a label that is attached to the joist plate base 1802 or can be printed, etched, or otherwise marked on the joist plate base 1802 in any suitable manner, including using the marking processes previously described.

As discussed above, the ICBC components with their respective markings and pre-installed elements can make the assembly process much easier than traditional construction processes. One such improvement is that the various stages or factors of the construction process can be completed without the need to reference detailed construction drawings or architectural blueprints. In traditional processes, complicated surveying and layout processes are used to determine the footprint of a building project and to create the layout for the foundation. The grid templates 600 previously described can be used to define the layout of a building project without detailed measuring.

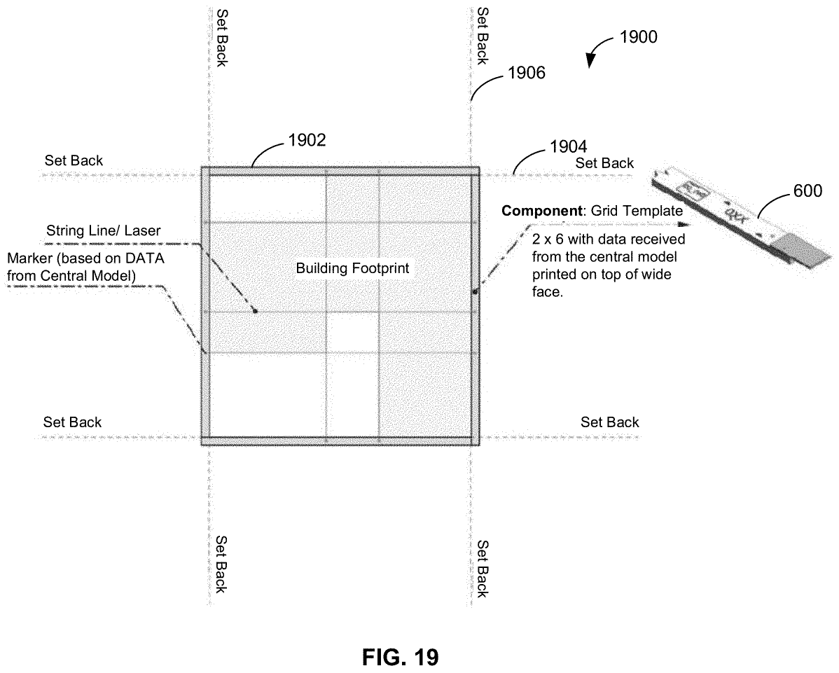

As shown in FIG. 19, the layout 1900 can be defined by assembling the the grid templates 600 to define a rectilinear footprint 1902 for the building project. A surveyor can mark a first perpendicular setback line 1904 and a second perpendicular setback line 1906 on the property of the building project. The assembled grid template 1902 is positioned and aligned with the first setback line 1904 and the second setback line 1906. In this manner, the grid template 1902 is easily positioned on the property without complicated surveying and measuring. The grid template 1902 can also include various layout markings on the surface of the grid template 1902. Strings or lasers can be positioned at the markings to provide other layout information for the building project.

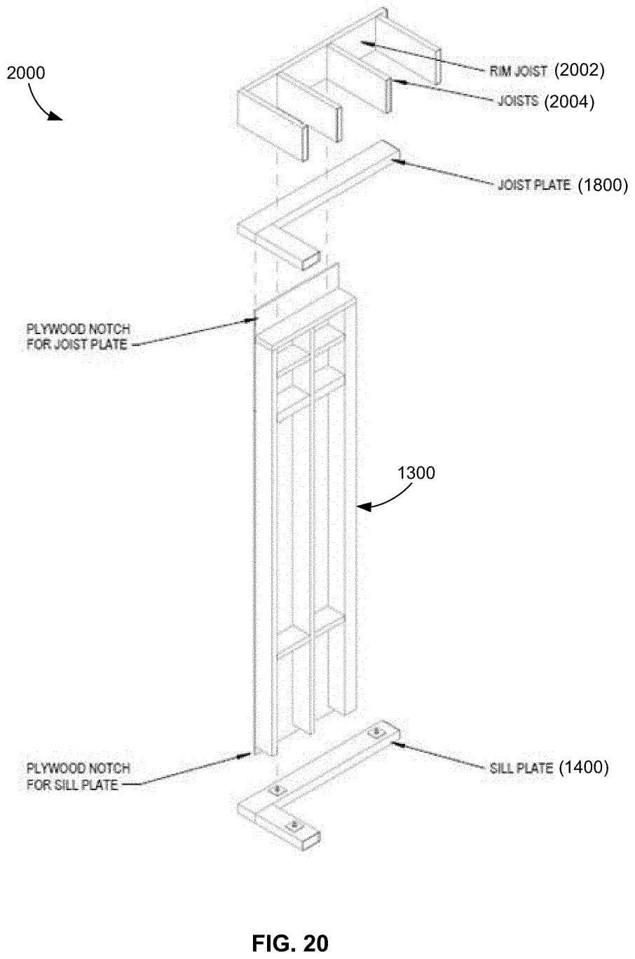

Once a layout is defined, the foundation for the building project can be formed using suitable construction processes. An example building assembly 2000 is shown in FIG. 20. The example building assembly 2000 can be constructed using one or more of the previously describe ICBC components when such components are delivered at the building site. As shown, the sill plate 1400 can be positioned on the foundation, for example, and can be lower portion of the building assembly 2000. As indicated by the sill marking 1406, the wall section 1300 can be positioned on the sill plate 1400 an attached thereto. The joist plate 1800 can be attached at a top of the wall section 1300 and the rim joist 2002 and joists 2004 can be attached to the top of the joist plate. The building assembly 2000 shows an example structure that can be assembled using the ICBC components previously described. As can be appreciated other structures and assemblies can also be constructed to create the entire construction project as is defined by the centralized construction model 108.

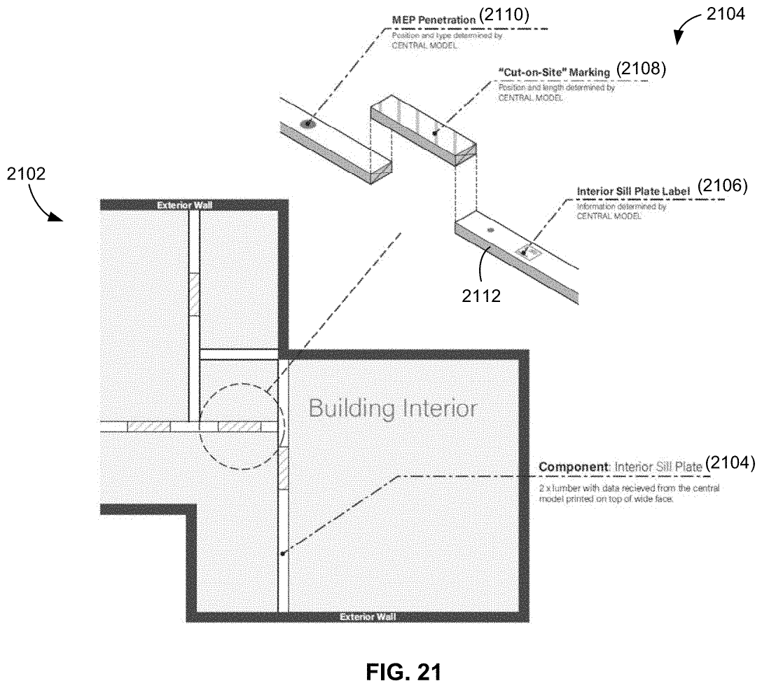

The interior structure of the building project can be similarly constructed as shown in FIG. 20. As shown in FIG. 21, the interior layout 2102 can be formed using interior sill plates 2104. The interior sill plates 2104 can be similar to the sill plates 1400 previously described. The interior sill plates 2104, however, for the interior walls and structure of the interior layout 2102. An example interior sill plate 2104 can include an interior sill base 2112 that can be a piece of lumber such as a two by four or the like. An interior sill plate marking 2106 can be fixed to an exterior surface of the interior sill base 2112. The interior sill plate marking 2106 can include indicators similar to those described with respect to the sill marking 1406. The interior sill plate marking 2106 can include cut-on-site indicators 2108 that indicate a portion of the interior sill plate 2104 that is to be removed after the interior sill plate 2104 is positioned in the interior layout 2102. The cut-on-site indicator(s) 2108 define door openings and the like that need to be removed. As further shown, the interior sill plate marking 2106 can also include one or more MEP indicators 2110 that can indicate a hole or position of a mechanical, electrical or plumbing line that is to be routed through the interior sill plate. The MEP indicators 2110 can indicate holes or openings that can be cut by the fulfillment centers 126 prior to delivery. The cut-on-site indicators 2108 can indicate cuts or portions of the interior sill plate 2104 to be removed at the building site.

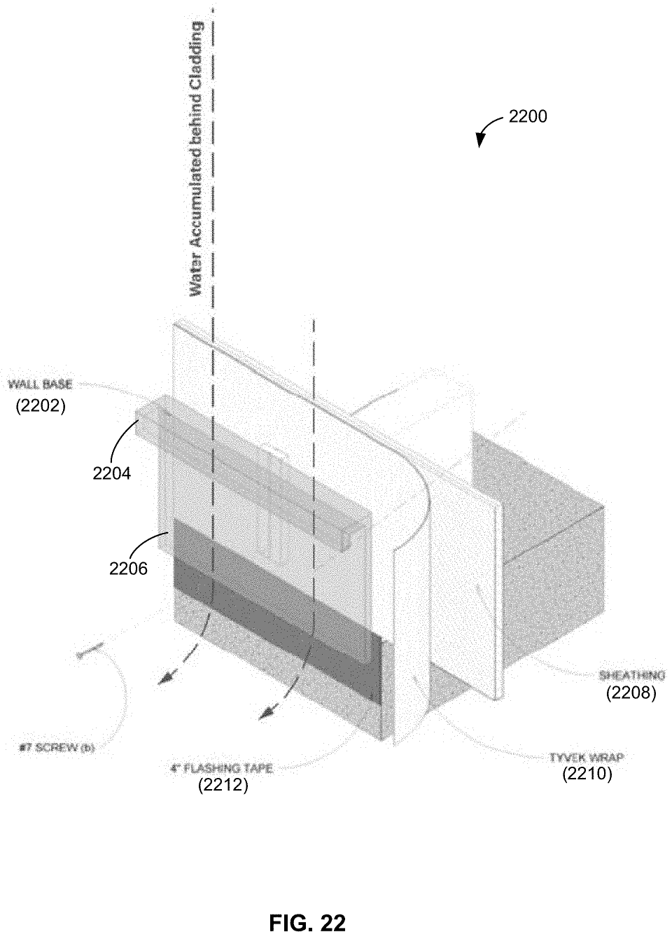

Referring now to FIG. 22, and exterior base assembly 2200 is shown. The exterior base assembly 2200 can be constructed at a lower edge of the exterior siding of the construction project. The exterior base assembly 2200 can make use of another ICBC component, namely wall base 2202. The wall base 2202 can be formed of a polyvinyl chloride (PVC) or other plastic material and can be extruded or otherwise formed to have an upper lip 2204 and a wall member 2206. The upper lip 2204 can have a downward facing rectangular lip (as shown) or other downward facing curl or concave shape. The wall member 2206 is substantially flat and configured to be secured to outside of the exterior walls of the building project. As shown, the wall base 2202 can be fixed to an exterior of sheathing 2208 and an exterior of sheathing wrap 2210 (e.g., Tyvex® wrap). The wall base 2202 can also be fit over an exterior of the flashing tape 2212. In this position, water that may accumulate behind the cladding can pass behind the wall base 2202 and flow out of the building structure.

The wall base 2202 can be installed around the exterior of the building structure. In order to form the wall base 2202 around the structure, straight portions, insider corners and outside corners can be ICBC components that are bundled and delivered to the building site from the fulfillment centers 126. The quantity of such components can be determined by the centralized construction model 108.

Still other ICBC components can also be used in the construction of building projects using the principles and methods of the present disclosure. Other example ICBC components can include the following:

Accent Cladding—exterior ornamental sheets for installation to exterior walls

Angle Splice—preformed rebar for corners of foundation

Ceiling Suspender—metal stud with lip to support ceiling

Column—structural support member

Coping—barrier for installation on top of wall sections at roof line

Coping Corners—pre-formed corners to join lengths of coping

Corner Trim—preformed trim for around exterior windows or other features

Door Fin—preformed trim for around exterior doors

Drain Assemblies—preformed piping for sink, shower or tub drains

Duct Registers—pre-assembled duct connections for HVAC

Electrical Meter Base—pre-assembled member to mount an electric meter

Entry Station—structure near entry ways

Doors—pre-assembled doors with hardware

Formworks—walls for formation of foundation

Furring Strips—pre-cut strips for leveling surfaces

Hairpin—formed rebar for foundation

L-clips—clips used to secure coping or other members at roof line

Pad Footing—footing for use in rebar layout for foundation

Saddle—preformed cover for top of walls at roof line

Stairs—pre-assembled stairs that can be secured in place

Vent Cap—cap positioned around vent on roof

Vent Coping—coping positioned around vent when vent exits wall

The above list is not comprehensive and it should be appreciated that other ICBC components can also be used.

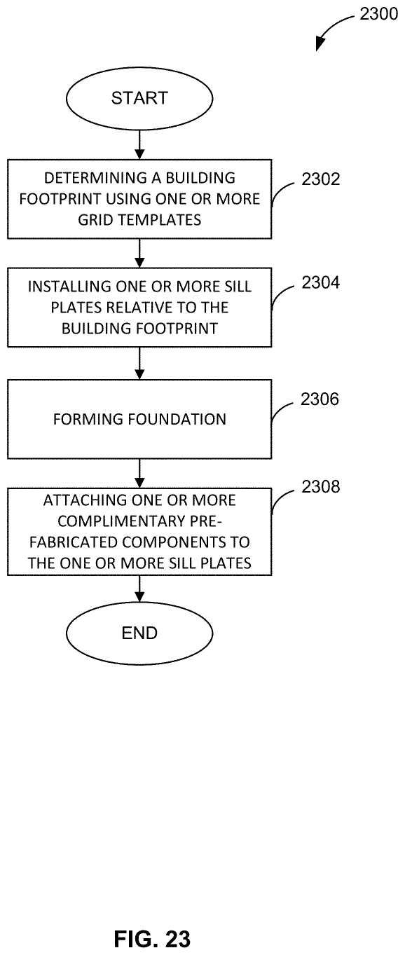

Referring now to FIG. 23, an example method 2300 of assembling a building project using ICBC components is shown. While not shown, the building project can be designed and a centralized construction model can be prepared. The coordination platform can determine a construction plan using the centralized construction model. The construction plan can separate stages of assembly into one or more factors. Each factor includes various pre-fabricated ICBC components that are fabricated by the fulfillment centers and then delivered to the building site for each separate factor. The method 2300 contemplates more than one factor and describes aspects of construction using the ICBC components of the present disclosure that provide improvements over existing or traditional construction methods. Such improvement include improved efficiency, the ability to assemble the components without consulting detailed architectural or construction drawings and reduced reliance on specialized knowledge of tradespeople.

The method 2300 starts with step 2302. At step 2302, a building footprint is determined using one or more grid templates. The building footprint can provide a layout for the building project and its orientation and location on a building site. An example building layout is shown in FIG. 19. In one example of determining the building footprint, the grid templates can be joined to one another as indicated by the markings fixed to each of the grid templates. The grid templates can also be aligned with one or more set back lines that can be marked on the building site during the course of a survey. Since only two set back lines are required, the need for complex measuring and surveying is reduced.

At step 2304, one or more sill plates can be installed relative to the building footprint. As previously described, the sill plates can each include a marking fixed on an exterior surface that indicates a unique identifier and the location of other components that will be installed one the sill plates. The marking can include the indicators previously described as well as other indicators. The indicators can indicate a location of MEP components, wall sections, framing members, and the like. The indicators can also indicate a location of attachments such as anchor bolts and/or hold downs. These components can be installed into the sill plates such that they are positioned in a predetermined manner as set forth in the centralized construction model.

At step 2306, the foundation can be formed. The foundation can be poured concrete or other suitable forming process. While not shown, the trenching and other pre-forming of the foundation can also be performed.

At step 2308, one or more complimentary pre-fabricated components can be attached to the sill plates. For example, the sill plate may include an attachment indicator that indicates a location for attachment of an anchor bolt or a hold down. The anchor bolts and/or hold downs can be connected to the sill plates at the location indicated by the attachment indicator of the sill marking. The anchor bolts and/or the hold downs can be connected to sill plate before the foundation is poured. In such an instance, the anchor bolts and/or the hold downs are positioned in the desired locations and then become embedded in the concrete foundation in the desired locations. Other complimentary pre-fabricated components can also be attached to the sill plates at the locations indicated on the sill marking. Such other complimentary pre-fabricated components can include wall sections, MEP components, and the like.

While not shown, the assembly of the building project can include other steps such as the connection and/or assembly of other pre-fabricated components, including the ICBC components described above.

The example methods and apparatuses described herein may be at least partially embodied in the form of computer-implemented processes and apparatus for practicing those processes and/or the described functionality. The disclosed methods may also be at least partially embodied in the form of tangible, non-transient machine readable storage media encoded with computer program code. The media may include, for example, RAMs, ROMs, CD-ROMs, DVD-ROMs, BD-ROMs, hard disk drives, flash memories, or any other non-transient machine-readable storage medium, or any combination of these mediums, wherein, when the computer program code is loaded into and executed by a computer, the computer becomes an apparatus for practicing the method. The methods may also be at least partially embodied in the form of a computer into which computer program code is loaded and/or executed, such that, the computer becomes an apparatus for practicing the methods. When implemented on a general-purpose processor, the computer program code segments configure the processor to create specific logic circuits. The methods may alternatively be at least partially embodied in a digital signal processor formed of application specific integrated circuits for performing the methods.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A construction component for use in integrated component-based construction comprising:
a base member having a predetermined size; and
a marking fixed to an exterior surface of the base member, the marking comprising an identifier and at least one indicator;
wherein the identifier identifies the base member's location in a centralized building model and the at least one indicator indicates a location of a second construction component relative to the base member.

2. The construction component of claim 1, wherein the marking is a label that is adhesively connected to the base member.

3. The construction component of claim 1, wherein the marking is printed onto the base member.

4. The construction component of claim 1, wherein the base member is a sill plate.

5. The construction component of claim 1, wherein the base member is a grid template for use to define a building footprint.

6. The construction component of claim 1, wherein the base member is a beam.

7. The construction component of claim 1, wherein the base member is a ledger.

8. The construction component of claim 1, wherein the base member is a joist plate.

9. The construction component of claim 1, wherein the marking further comprises an orientation indicator that identifies an orientation of the construction component relative to a predetermined location in a building project.

10. The construction component of claim 1, wherein information on the marking is extracted from the centralized building model.

11. A method of assembling a building project comprising:
determining a building footprint on a building site using one or more grid templates;
attaching one or more pre-fabricated sill plates to a foundation, each sill plate comprising a sill marking comprising one or more indicators indicating a location or orientation of one or more complimentary pre-fabricated construction components; and
attaching the one or more complimentary pre-fabricated construction components relative to the one or more pre-fabricated sill plates at a location or in an orientation indicated by the one or more indicators.

12. The method of claim 11, wherein the one or more complimentary pre-fabricated construction components comprises a wall section.

13. The method of claim 12, wherein the wall section comprises one or more framing members and a sheathing.

14. The method of claim 11, wherein the one or more complimentary pre-fabricated construction components comprises an interior sill plate, the interior sill plate defining an interior wall of the building project.

15. The method of claim 14, further comprising removing a portion of the interior sill plate indicated by a cut-on-site indicator on an interior sill marking fixed on an exterior surface of the interior sill plate.

16. The method of claim 11, wherein the one or more indicators comprises an MEP indicator that indicates a location of a mechanical, electrical or plumbing component.

17. The method of claim 11, wherein the one or more indicators comprises an attachment indicator that indicates a location of anchor bolt or a hold down.

18. The method of claim 11, wherein the one or more grid templates comprises a base member and a grid marking fixed to an exterior surface of the base member, the grid marking indicating an orientation of the grid template relative to the building site.

19. The method of claim 18, wherein the step of determining the building footprint comprises joining the one or more grid templates and positioning the one or more grid templates as indicated by the grid marking.

20. The method of claim 19, wherein the step of positioning the one or more grid templates further comprises aligning the one or more grid templates to at least two set back lines provided by a survey of the building site.
